(19) United States
(12) Patent Application Publication
(10) Pub. No.: US 2004/0256146 A1
(43) Pub. Date: Dec. 23, 2004

(54) Electrode structure and methods for producing and using the same

(75) Inventors: Matthias Frericks, Hanau (DE); Frank Kruger, Bruchkobel (DE)

Correspondence Address: AKIN GUMP STRAUSS HAUER & FELD L.L.P., ONE COMMERCE SQUARE, 2005 MARKET STREET, SUITE 2200, PHILADELPHIA, PA, 19103-7013, US

(73) Assignee: W.C. Heraeus GmbH & Co., KG

(21) Appl. No.: 10/870,807

(22) Filed: Jun. 17, 2004

(30) Foreign Application Priority Data
Jun. 17, 2003 (DE) 103 27 500.2

(51) Int. Cl. H01L 21/00; H05K 3/00

(52) U.S. Cl. 174/254; 29/847; 29/846; 174/250; 29/829

(57) ABSTRACT

A method is provided for producing electrode structures which have a supply line and a contact surface connected thereto, wherein a planar electrode material is roll bonded onto a planar carrier material and the thickness of the electrode material and carrier material is reduced by rolling. The electrode material is then structured with formation of contact surfaces and supply lines in its surface, and predefined parts of the electrode material are removed. Then, electrode material located on the carrier material is coated with a sealing compound or a foil, and the carrier material is then removed. The structure may be used in medical implants for neuro stimulation and/or muscular stimulation, for example in a cochlear implant, a retina implant, or a cortical electrode.

### BACKGROUND OF THE INVENTION

The invention is directed to a method for producing electrode structures, which have a supply line and a contact surface connected to this supply line. The invention is further directed to corresponding electrode structures and their use.

Such electrode structures are known, for example, from International application publication WO 02/089907 A1. In the method described there, a foil is applied to a carrier, and the foil is then structured accordingly. The electrodes produced from the foils are used for stimulation as cochlear implants. Such implants are also described in detail in WO 02/089907 A1.

The production of cochlear electrodes, which are arranged on a flexible, tubular carrier, is taught by U.S. Pat. No. 6,266,568 B1.

### BRIEF SUMMARY OF THE INVENTION

The present invention is based on the object of creating a method for producing electrode structures, which can be manufactured economically in one piece and with smaller overall sizes. Furthermore, uses for the electrode structures according to the invention will also be described.

In the method according to the invention, a planar electrode material is roll bonded onto a planar carrier material, and the thickness of the electrode material and carrier material is reduced by rolling. The electrode material is then structured in its surface with formation of contact surfaces and supply lines. Defined parts of the electrode material are removed, and the electrode material located on the carrier material is then coated with a sealing compound or a foil. The carrier material can then be removed.

With the cold working performed here, a wide range of mechanical properties can be adjusted. The higher the degree of cold working, the higher the achievable mechanical strength. The roll bonding is more economical than production according to the prior art. The necessary degree of deformation can be set freely. Thus, relatively large layer thicknesses can be achieved, so that longer supply lines with lower electrical resistance are possible due to a larger cross section. Since both the electrode material and the carrier material start from relatively large material thicknesses at the time of roll bonding, a series of possible material choices arises. Expediently, the rolling to reduce the thickness is at first performed simultaneously with the roll bonding. Accordingly, the desired final thickness can be set by several rolling passes.

Suitable electrode materials are especially metals selected from the group Pt, Ir, Au, W, Ta, Nb, or an alloy with at least one of these metals. Expediently, the carrier materials can be metals or alloys, preferably Cu and/or Fe or their alloys or a plastic. The choice of materials allows the adjustment of properties of the electrode structures, for example to obtain soft, easily pliable electrode structures or those with high tensile strength or fatigue strength (under great mechanical loading or variable bending force). For example, by alloying iridium with platinum, the tensile strength can be changed from below 250 N/mm² (PtIr5, annealed) to over 2000 N/mm² (PtIr30 with high cold working). High strengths can also be achieved with PtAu alloys (e.g., PtAu5). PtW alloys (e.g., PtW8) have especially good fatigue strengths. With tantalum alloys the strength can be increased with increasing tungsten fraction. Platinum and its alloys have a high biocompatibility, independent of the electrical polarity of the electrodes.

The biocompatible electrode structures are usually chemically stabile, so that the carrier material can be selected such that, for example, it can be easily removed by an etching process after the electrode structures have been produced.

Expediently, the structures are generated by a photolithographic process, wherein the parts of the electrode material not forming the electrode material are removed as predefined parts by subsequent etching (particularly chemical etching, electrochemical etching, or dry etching).

For photolithographic structuring, a photoresist material in the form of a foil or a liquid is preferably used. The photolithographic method has a much higher flexibility for the geometries to be produced than, for example, the EDM method known from WO 02/089907 A1. Photolithographic methods are also significantly more efficient, because large electrode structures with a large plurality of electrodes can be treated simultaneously. Dry etching/plasma etching has the advantage that different materials can be structured with the same method.

Therefore, an alternative to the method according to the invention for producing electrode structures, which have a supply line and a contact surface connected to the supply line, consists in applying a planar electrode material on a planar carrier material, wherein the electrode material is then structured with formation of the contact surfaces and supply lines in its surface. Defined parts of the electrode material are removed by dry etching, and the electrode material located on the carrier material is then covered with a sealing compound or a foil. Thereafter, the carrier material is removed.

Preferably, for the electrode material a material is used from the group including platinum alloys, gold, gold alloys, tantalum, tantalum alloys, niobium, niobium alloys, cobalt-chromium-nickel alloys, stainless steel, and nickel-titanium alloys, wherein the platinum alloys in particular are formed with at least one metal from the group including gold, tungsten, and iridium.

The electrode structure according to the invention, made from a plurality of electrodes, which are electrically insulated from each other and which have supply lines and contact surfaces connected to these lines, has supply lines and associated contact surfaces made from one piece, which is formed from a material from the group including platinum alloys, gold, gold alloys, tantalum, tantalum alloys, niobium, niobium alloys, cobalt-chromium-nickel alloys, stainless steel, and nickel-titanium alloys, wherein the platinum alloys have particularly gold, tungsten, and/or iridium. The niobium alloy is formed especially with zirconium.

The supply lines are advantageously at least partially held in a common electrically non-conductive matrix, wherein the matrix can expediently be formed from a flexible material.

It is expedient if the electrodes are formed with a planar shape. Furthermore, it is expedient if the electrodes have a thickness greater than 3 μm up to approximately 15 μm or, if very thin electrodes are needed, they may have a thickness of approximately 0.1 μm up to 3 μm.

The supply lines expediently have a width greater than 20 μm up to approximately 60 μm, but instead can particularly have a width of approximately 2 μm to 20 μm, if finer structures are required.

In particular, it is expedient if the width of the contact surfaces is greater than or equal to the width of the supply lines.

According to the invention, the electrode structures can be used as medical implants, for neurostimulation and/or muscle stimulation, as cochlear implants, as retina implants, or as cortical electrodes.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a series of cross-sectional views of the electrode structure schematically showing the production of the electrode structures according to the invention; and

FIG. 2 is a perspective view of a finished electrode structure according to the invention.

### DETAILED DESCRIPTION OF THE INVENTION

Initially, as the electrode material 1, PtIr10 is rolled onto the carrier material 2 made of copper. Starting with a 1-mm thick platinum alloy sheet and a 9-mm thick copper sheet, a final thickness of 10 μm for the platinum alloy and 90 μm for the copper sheet is achieved by roll bonding or rolling. A commercially available negative photoresist 3 with a thickness of 38 μm is applied to the electrode material 1. Then, a photomask 4 (glass mask) is applied, which reproduces the structures to be realized. The material is then brought for this purpose into an illumination device, whose component is the photomask 4. Illumination is realized by means of UV light 5. Then, the structure of the photoresist 3 is developed, and subsequently the layer of the electrode material 1 is plasma etched.

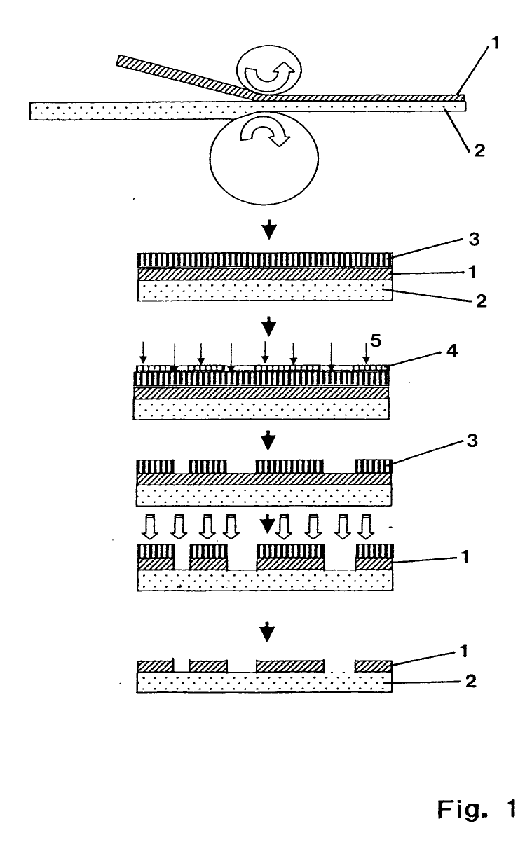

After removing the photoresist 3, the electrode structure of the electrode material 1 is available on the carrier material 2. The corresponding sequence is shown in FIG. 1 from top to bottom. After the photoresist 3 has been removed, the electrode structures are sealed in silicone and the carrier material 2 is removed. Besides silicone, other polymers can also be used as sealing compounds, for example, polyimides, polyurethane, parylene, or polyaryl ether ether ketone (PEEK).

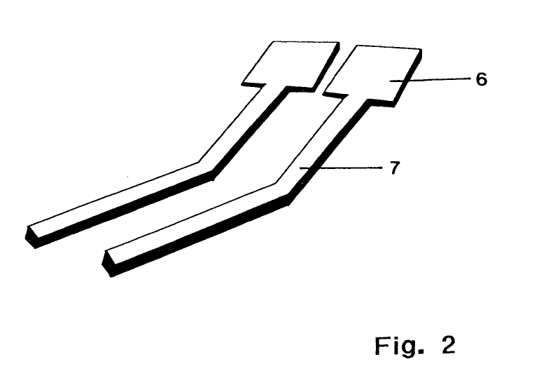

FIG. 2 shows an exemplary embodiment for illustrating the final electrode structures. Obviously, the contact surfaces 6 and the supply lines 7, respectively, can also be configured in other shapes. For example, the contact surfaces 6 can be circular or oval. In FIG. 2 the supply lines are slightly angled. This can be required for further processing or in the particular application. FIG. 2 shows two contact surfaces 6 with supply lines 7, merely as examples. In the concrete application, as a rule several such structures are required to provide stimulation at several locations. The polymer structure is not shown in FIGS. 1 and 2 for sake of overview, but such an arrangement can be readily realized by one skilled in the art from the prior art.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method for producing electrode structures which have a supply line and a contact surface connected to the supply line, comprising roll bonding a planar electrode material onto a planar carrier material, reducing a thickness of the electrode material and the carrier material by rolling, then structuring the electrode material with formation of contact surfaces and supply lines in a surface of the planar electrode material, removing predefined parts of the electrode material, then coating the electrode material located on the carrier material with a sealing compound or a foil, and then removing the carrier material.

2. The method according to claim 1, wherein the roll bonding and the rolling to reduce the thickness are performed simultaneously.

3. The method according to claim 1, wherein the electrode material comprises a metal selected from the group consisting of Pt, Ir, Au, W, Ta, Nb, and alloys with at least one of these metals.

4. The method according to one of claim 1, wherein the carrier material comprises a material selected from the group consisting of a metal, an alloy, and a plastic.

5. The method according to one of claim 4, wherein the carrier material comprises a metal or an alloy selected from the group consisting of Cu, Fe and their alloys.

6. The method according to one of claim 1, wherein the structuring is performed by a photolithographic process, and the predefined parts of the electrode material are removed by subsequent etching.

7. The method according to claim 6, wherein the photolithographic process uses a photoresistive material in a form of a foil or a liquid.

8. The method according to claim 6, wherein the etching is performed as chemical etching, electrochemical etching, or dry etching.

9. A method for producing electrode structures which have a supply line and a contact surface connected to the supply line, comprising applying a planar electrode material to a planar carrier material, then structuring the electrode material with formation of contact surfaces and supply lines in a surface of the planar electrode material, removing predefined parts of the electrode material by dry etching, then coating the electrode material located on the carrier material with a sealing compound or a foil, and then removing the carrier material.

10. The method according to claim 9, wherein the electrode material forming the supply lines and contact surfaces comorises a material selected from the group consisting of platinum alloys, gold, gold alloys, tantalum, tantalum alloys, niobium, niobium alloys, cobalt-chromium-nickel alloys, stainless steel, and nickel-titanium alloys, wherein the platinum alloy is formed from at least one metal selected from the group consisting of gold, tungsten, and iridium.

11. An electrode structure comprising a plurality of electrodes electrically insulated from each other, each electrode having supply lines and contact surfaces connected thereto, wherein the supply lines and associated contact surfaces are each formed of one piece from a material selected from the group consisting of platinum alloys, gold, gold alloys, tantalum, tantalum alloys, niobium, niobium alloys, cobalt-chromium-nickel alloys, stainless steel, and nickel-titanium alloys.

12. The electrode structure according to claim 11, wherein the platinum alloy is formed from at least one metal selected from the group consisting of gold, tungsten, and iridium.

13. The electrode structure according to claim 11, wherein the niobium alloy is formed with zirconium.

14. The electrode structure according to claim 11, wherein the supply lines are held at least partially in a common electrically non-conductive matrix.

15. The electrode structure according to claim 14, wherein the matrix comprises a flexible material.

16. The electrode structure according to claim 11, wherein the electrodes are formed with a planar shape.

17. The electrode structure according to claim 11, wherein the electrodes have a thickness of greater than 3 μm up to approximately 15 μm.

18. The electrode structure according to claim 11, wherein the electrodes have a thickness of approximately 0.1 μm up to 3 μm.

19. The electrode structure according to claim 11, wherein the supply lines have a width of greater than 20 μm up to approximately 60 μm.

20. The electrode structure according to claim 11, wherein the supply lines have a width of approximately 2 μm up to 20 μm.

21. The electrode structure according to claim 11, wherein the width of the contact surfaces is greater than or equal to the width of the supply lines.

22. The electrode structure according to claim 11, wherein the structure is at least part of a medical implant.

23. The electrode structure according to claim 22, wherein the structure is adapted for neurostimulation and/or for muscle stimulation.

24. The electrode structure according to claim 22, wherein the structure is at least part of a cochlear implant, a retina implant, or a cortical electrode.
